(19) United States
(12) Patent Application Publication
(10) Pub. No.: US 2010/0311248 A1
(43) Pub. Date: Dec. 9, 2010

(54) STRUCTURED LAYER DEPOSITION ON PROCESSED WAFERS USED IN MICROSYSTEM TECHNOLOGY

(75) Inventor: Roy Knechtel, Geraberg (DE)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(73) Assignee: X-Fab Semiconductor Foundries AG, Erfurt (DE)

(21) Appl. No.: 12/664,272

(22) PCT Filed: Jun. 16, 2008
(86) PCT No.: PCT/EP08/57579

§ 371 Date: Aug. 23, 2010

(30) Foreign Application Priority Data
Jun. 14, 2007 (DE) 10 2007 027 435.3

(51) Int. Cl. H01L 21/30; B05C 3/20

(52) U.S. Cl. 438/758; 118/669; 257/E21.211

(57) ABSTRACT

The invention relates to a method and a through-vapor mask for depositing layers in a structured manner by means of a specially designed coating mask which has structures that accurately fit into complementary alignment structures of the microsystem wafer to be coated in a structured manner such that the mask and the wafer can be accurately aligned relative to one another. Very precisely defined portions on the microsystem wafer are coated through holes in the coating mask, e.g. by mans of sputtering, CVD, or to evaporation processes.

### CROSS-REFERENCE TO RELATED APPLICATIONS

The application is a U.S. National Stage Application of International Application of PCT/EP2008/057579 filed Jun. 16, 2008, which claims the benefit of German Patent Application No. 10 2007 027 435.3 filed Jun. 14, 2007, the disclosures of which are herein incorporated by reference in their entirety.

### FIELD OF THE DISCLOSURE

The invention relates to structured layer deposition on processed wafers used in microsystem technology. A suitable method and a suitable device are being proposed.

### BACKGROUND OF THE DISCLOSURE

When processing wafers for producing microstructure systems on suitable substrate wafers, e.g. semiconductor wafers, e.g. provided in the form of silicon wafers, which is abbreviated herein as wafer processing by microsystem technology, it is very often required that the semiconductor wafers or chip structures are partially provided with layers, this means in a structured manner during or at the end of the production of complex micro-electromechanical structures. Thus, the typical multilayer technology which is based on full-surface deposition of the layer and its subsequent photochemical structuring typically cannot be used efficiently. Either certain portions of the wafers/chips must not be coated at all, since this coating would e.g. render micromechanical structures unusable, or a photochemical structuring is not possible due to a pronounced surface profile and/or presence of layers, which cannot be etched or the complexity is too great.

Coating masks have been known for a long time, which comprise openings for the material to be deposited. Such masks e.g. made from metal are problematic insofar as misalignments occur when surfaces are highly profiled, and the structures to be deposited are thus not precisely defined. This way, disadvantages with respect to quality, yield and density of packaging are created. The poor adjustability of such hard masks also has a detrimental effect for the microstructures.

### SUMMARY OF THE DISCLOSURE

It is the object of the invention to provide a method and a device for structured layer deposition on processed microsystem technology wafers which overcome said disadvantages of the prior art and which improve the quality of the process.

In one aspect, the object is accomplished by a method with the subsequent steps: providing two or plural mechanical alignment structures at the microsystem wafer, providing a through-vapor mask with two or more mechanical mask alignment structures, which are configured with respect to their shape and position to mechanically to engage two or more mechanical alignment structures at the microsystem wafer. Furthermore, two or more mechanical alignment structures of the microsystem wafer are brought into contact with the two or more mechanical mask alignment structures of the through-vapor mask, and material is selectively applied to the microsystem wafer through openings, which are provided in the through-vapor mask. Eventually, the through-vapor mask is lifted off after material has been applied selectively.

Thus, the invention provides a method which is based on using a particular coating mask as a through-vapor mask and, in particular, an alignment system for the coating mask and the microsystem technology wafer, which increases the alignment precision and the exact definition of the structured layers to be deposited. Thus, a structure is provided in the method according to the invention, which is designated as mechanical in the sense that the connection of the alignment structures on the mask and on the wafer is implemented through them mechanically engaging one another, so that a mechanical fixation or locking is implemented with respect to relative rotation and relative lateral movement. The alignment structures on the wafer and on the mask are thus configured as complementary structures, e.g. by protrusions and recesses complementary thereto (in corresponding numbers).

After the desired material has been deposited through the openings of the through-vapor mask, it can be lifted off again and can be used for selectively coating another wafer.

In advantageous embodiments, the alignment structures provide a self-adjusting action, in that suitable fixation, locking or contact surfaces of the mask alignment structures and surfaces complementary thereto are provided on/in the wafer, which alignment structures facilitate a relative sliding movement until the desired lateral relative position is achieved. This can be implemented through a conical configuration of the respective recess and through a complementary conical protrusion.

The method according to the invention can be used with many types of material deposition or coating, e.g. CVD, PVD, etc.

Furthermore, the method can also be integrated efficiently into the entire production process for generating microsystem structures on wafers, since the alignment structures can be produced at the wafers together with the component structures.

In another aspect of the present invention, a through-vapor mask is provided, which can be used multiple times for selective material deposition on microsystem wafers.

Multiple uses are advantageous. Several wafers have alignment structures, which fit those alignment structures that are disposed at the mask.

The thickness of the mask is preferably less than 1 mm. As a disc, it can be made of a composite of several materials.

Several advantageous embodiments of the mask and of the method recited supra can be derived from the additional claims and also from the subsequent description.

### BRIEF DESCRIPTION OF THE DRAWINGS

The invention will now be described in more detail with reference to exemplary embodiments and schematic drawing figures, wherein:

FIG. 1 schematically illustrates a sectional view of an assembly made of a microsystem technology wafer 2 and a coating mask 1 as a through-vapor mask in a pre-adjusted position, wherein the through-vapor mask is not applied yet. Various types of alignment structures 4a, 4b or 5a, 5b are illustrated;

FIG. 2 schematically illustrates a cross sectional view of the microsystem technology wafer 2 with a coating mask 1 applied during a vapor deposition process;

FIG. 3 schematically illustrates a cross sectional view of the microsystem technology wafer with elements 8, 8′ of the coated structure, wherein the mask 1 is removed; and

FIG. 4a, b illustrate details of two types of complementary alignment structures 4a, 4b or 5a, 5b of FIG. 1, which are not jointly illustrated in one depiction, but in two separate depictions as two particular embodiments. This applies accordingly for the structures 5′ and 4′ at the left edge of FIG. 1, which can be configured accordingly.

### DETAILED DESCRIPTION OF EXEMPLARY EMBODIMENTS

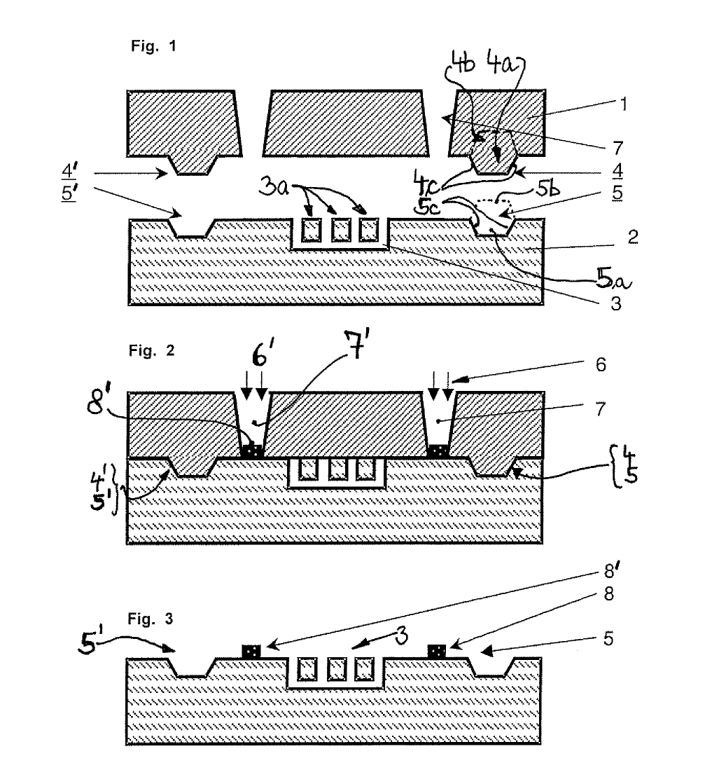

FIG. 1 illustrates a schematic cross sectional view of an assembly with a coating mask 1, which is also designated as through-vapor mask 1, for selectively coating one, and in is advantageous embodiments, several microsystem technology wafers 2 which comprise sensitive structures 3a in a portion 3, which is not to be coated. These structures shall not be coated.

In the illustrated embodiment, the coating mask 1 comprises at least two mechanically is acting alignment structures 4, 4′, which are also designated as mask alignment structures and configured precisely fitting into the alignment structures 5, 5′ on the microsystem technology wafer 2. The alignment structures 4 and 5 or 4′ and 5′ are complementary to one another in the sense that they can mechanically engage one another, thus facilitating a fixation of the relative position at least with reference to a rotation of the wafer 2 relative to the mask 1.

Thus, in the illustrated embodiment, alignment structures 4 and 5 are disposed with a matching geometry, i.e. with a complementary or inverse structure and position, respectively recessed in the wafer 2 as a recess 5a and respectively protruding at the through-vapor mask 1 as a protrusion 4a, so that they are configured to nest well into one another, and thus can bring the wafer 2 and the mask 1 into a very precisely defined position relative to one another in order to secure them against relative movement or rotation.

In other embodiments, the mask 1 comprises the alignment structures 4 in the form of a recess 4b, and the alignment structures 5 have a protrusion 5b (dashed lines in FIG. 1).

In other embodiments, both alignment structures 4 and 5 can respectively have protrusions and recesses, however, so that they are complementary with one another. One of the structures 4 can have a rise and another structure 4 can have a recess, so that the respective alignment structures 5 on the wafer have a recess or a protrusion. Protrusions and recesses in the form of a “fine structure” can also be provided within an alignment structure.

The same applies for the structures 5′ and 4′ on the other side of the sensitive microstructure 3a.

In one embodiment, the coating mask 1 and also the microsystem technology wafer 2 are made of silicon, so that identical structuring techniques, e.g. etching or similar can be used to form the alignment structures 4 and 5 and 4′ and 5′.

In other embodiments, the mask 1 and the wafer 2 can be made from different materials, so that desired properties can be implemented in particular with respect to the materials of the mask 1. This can occur with respect to reuse, with respect to the compatibility with process conditions during material deposition, with respect to cleaning the mask 1 or similar. The mask 1 can e.g. be made of one or several base layers or materials and a final layer is provided with a suitable thickness so that, on the one hand, the target dimensions are maintained and, on the other hand, the desired surface properties are achieved. For example, a layer in the range of several 10 nm made of SiN, SiC, SiO, etc. can be deposited in order to adjust the surface properties.

In one embodiment, however, a self-aligning effect of the alignment structures 4 and 5 is accomplished, in that the alignment structures 4 have slanted flanks 4c and the alignment structures 5 have complementary slanted flanks 5c, which facilitate an exact fitting of the coating mask 1 and of the wafer 2, so that a positioning precision in the micrometer range is achieved. The slanted flank yields a cone or a truncated cone in the sense of conicity for an alignment structure 4 and opposite conicity for the other alignment structure 5. The conicity can cover a section; the alignment elements preferably have a truncated cone shape with a flat end.

However, also any other mechanically exactly fitting combination of alignment elements is suitable.

FIG. 2 illustrates the coating mask 1 and the microsystem technology wafer 2 when they are joined, wherein the joining is performed manually or through contact pieces, e.g. through a wafer bond-aligner. Then the layer deposition 6 is performed through the openings 7, 7′ in the coating mask 1, which define the portions to be coated, so that the coated portions are created after the coating mask is lifted off.

FIG. 3 illustrates the wafer 2 after depositing the material through the process 6, which can include CVD, PVD, and template printing or similar. During processing in the process 6 and the disc handling linked therewith, typically the mechanical fit of the alignment markers 4 and 5 is sufficient for automatic handling in the coating systems. Optionally, however, the wafer 2 and the mask 1 can be additionally secured relative to one another through clamping.

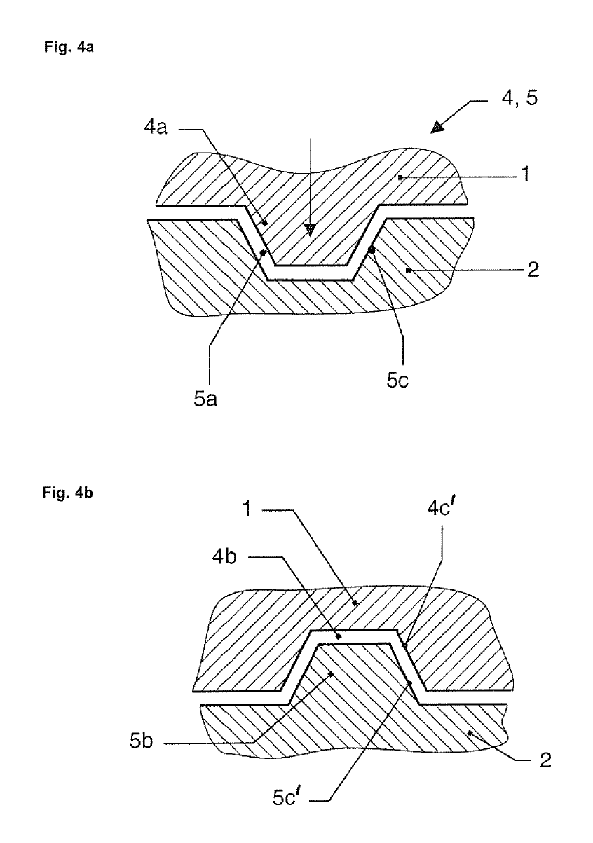

FIGS. 4a and 4b are detail enlargements of two types of complementary alignment structures 4a, 4b or 5a, 5b of FIG. 1, wherein they are depicted here in two separate depictions as two particular embodiments. This applies for the structures 5′ and 4′ at the left edge of FIG. 1, which can be configured accordingly.

The alignment element 4a is a protrusion at the mask, which is configured with inclined flanks configured for aligning insertion into the recess 5a with flanks 5c, which are accordingly inclined. The alignment element 5b is a protrusion configured with inclined flanks 5c′ at the microsystem technology wafer 2, configured for aligning insertion into the recess 4b with accordingly inclined flanks 4c′.

The method is suitable for various coating processes, like metalizing through sputtering and evaporating, but also for the deposition of the dielectric layers in CVD processes and even for template print, wherein the coating mask 1 serves as a template in this case. For practical reasons, thus with respect to wafer handling, the structuring, the stability, etc., the thickness of the coating mask 1 (through vapor mask) is configured in a suitable manner. A thickness of a few 100 micrometers is suitable for many situations when manufacturing microstructures. Thus, a thickness in the range of 100 μm up to 900 μm can be used or substantially the same thickness can be used as for the wafer 2.

When creating the actual component structures, thus the structure 3, a plurality of process techniques is being used, e.g. layer deposition, lithography, etching and similar, wherein at least some of these processes can also be used to generate the alignment structures 5, 5′ in the wafer 2. For example, the structures 5, 5′ can be formed as recesses 5a during an etching process, in which also other recesses for the actual components (structures 3) are being formed, wherein a suitable lithography mask can provide the desired lateral dimensions. In other cases suitable process steps are inserted over the course of the production, in order to produce the structures 5 in the desired geometry without creating any disadvantageous interference into the entire process.

In a particular embodiment, a selective coating 8 of the structured microsystem technology wafer 2 is performed, wherein the coating is performed through the openings 7 in a multiuse coating mask applied to the wafer 2. The mask 1 covers portions 3 of the microsystem technology wafer 2 which are not to be coated, wherein mechanical alignment structures 4 and 5 are disposed on the microsystem technology wafer 2 and on the coating layer 1 in exactly the same position and with identical distances from one another. The alignment structures on the coating mask 1 are protrusions and those on the microsystem technology wafer 2 are recesses or vice versa.

When applying the coating mask 1, a self-alignment of the coating mask 1 relative to the microsystem technology wafer 2 is performed.

After the coating process of the layer or of the layer portion 8, the coating mask 1 is lifted off. The mask 1 can be reused for the next coating process employing the same method.

1. A method for selectively coating a structured microsystem technology wafer, comprising the following steps:
providing two or more mechanical alignment structures at the microsystem technology wafer;
providing a through-vapor mask with two or more mechanical mask alignment structures, which are configured with respect to their shape and position to provide a mechanical engagement with the two or more mechanical alignment structures at the microsystem wafer;
bringing the mechanical alignment structures of the microsystem wafer in contact with the mechanical mask alignment structures the through-vapor mask;
selectively applying material to the microsystem wafer through at least one opening, which is provided in the through-vapor mask; and
lifting the through-vapor mask off after material has been applied selectively.

2. The method according to claim 1, wherein the two or more mechanical alignment structures and the two or more mechanical mask alignment structures comprise protrusions and/or recesses, preferably with inclined flanks, which provide a self-aligning effect for the mask relative to the wafer when brought into contact.

3. The method according to claim 1, furthermore comprising the following steps: providing another microsystem wafer, which comprises respective mechanical alignment structures, bringing the through-vapor mask in contact with the other microsystem wafer, and selectively applying material to the other microsystem wafer.

4. The method according to claim 2, wherein the mechanical alignment structures and the mechanical mask alignment structures are configured conically at least in sections.

5. The method according to claim 1, wherein providing the two or more mechanical alignment structures comprises the following:
creating the mechanical alignment structures at or in particular on the microsystem technology wafer simultaneously with other structures.

6. The method according to claim 1, wherein applying the material is performed through evaporating, through PVD (Physical Vapor Deposition), CVD (Chemical Vapor Deposition) or through template printing.

7. A through-vapor mask for selective and sequential coating microsystem technology wafers, the through-vapor mask is adapted to be multi-reusable or reused several times and comprising:
two or more mechanical mask alignment structures, which correspond with respect to their position and distance at least with two complementary mechanical alignment structures at least at one microsystem technology wafer; and
mask openings, adapted with respect to their lateral size and position with respect to mask alignment structures for selectively depositing material on the microsystem wafers.

8. The Multi-reusable through-vapor mask according to claim 7, wherein the mask alignment structures comprise protrusions and/or recesses.

9. The Multi-reusable through-vapor mask according to claim 7, wherein the mask alignment structures comprise protrusions and the complementary alignment structures comprise recesses in at least two microsystem technology wafers.

10. The Multi-reusable through-vapor mask according to claim 7, wherein the mask alignment structures comprise recesses and the complementary alignment structures comprise protrusions at least at two microsystem technology wafers.

11. The Multi-reusable through-vapor mask according to claims 7, wherein each of the mask alignment structures comprises at least one inclined flank, which has a self-aligning effect with a respective flank at the respective wafer inclined in a complementary manner.

12. The Multi-reusable through-vapor mask according to claim 11, wherein the mask alignment structures are configured conical, in particular flattened at their ends.

13. The Multi-reusable through-vapor mask according to claim 7, which is made of silicon or glass.

14. (canceled)

15. The Multi-reusable through-vapor mask according to claim 7, made of a composite made of glass and silicon.

16. The Multi-reusable through-vapor mask according to claim 7, having a thickness between 100 μm and 900 μm.

17. (canceled)

18. The through-vapor mask according to claim 7, wherein at least two microsystem technology wafers are provided, each comprising alignment structures and the mask alignment structures of the mask fit together with alignment structures of the at least two wafers in a self-aligning manner.

19. The method according to claim 1, wherein the alignment structure is connected integrally or bonded with the mask, and/or the alignment structure is connected integrally or bonded with the wafer.
